(19) United States
(12) Patent Application Publication
(10) Pub. No.: US 2010/0075477 A1
(43) Pub. Date: Mar. 25, 2010

(54) Method of Manufacturing Semiconductor Device

(75) Inventor: Ji Hyun Seo, Bucheon-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/495,240

(22) Filed: Jun. 30, 2009

(30) Foreign Application Priority Data
Sep. 22, 2008 (KR) 10-2008-0092777
Apr. 10, 2009 (KR) 10-2009-0031320

(51) Int. Cl. H01L 21/762; H01L 21/336

(52) U.S. Cl. 438/296; 438/424; 257/E21.422; 257/E21.546

(57) ABSTRACT

An embodiment of the disclosure relates to a method of manufacturing semiconductor devices. According to this embodiment, a tunnel insulating layer, a conductive layer for a floating gate, and a hard mask layer are sequentially formed over a semiconductor substrate. Isolation trenches are formed by etching the hard mask layer, the conductive layer for the floating gate, the tunnel insulating layer, and the semiconductor substrate. Isolation structures are formed by filling the isolation trenches with an insulating layer. Upper sidewalls of the isolation trenches are exposed by etching predetermined thickness of the isolation structures. Ion implantation regions are formed in the exposed upper sidewalls of the isolation trenches by performing an ion implantation process.

### CROSS-REFERENCE TO RELATED APPLICATION

Priority to Korean patent application number 10-2008-0092777 filed 22 Sep., 2008, and priority to Korean patent application number 10-2009-0031320 filed 10 Apr., 2009, the entire respective disclosures of which are incorporated by reference herein, are claimed.

### BACKGROUND

An embodiment of the disclosure relates to a method of manufacturing semiconductor devices and, more particularly, to a method of manufacturing semiconductor devices, which forms the isolation structures of the semiconductor devices.

In general, in order to separate semiconductor devices, a semiconductor substrate is defined into an active region and a field region, word lines are formed in the active region, and isolation structures for isolating devices are formed in the field region.

In order to form the isolation structures of the semiconductor devices, trenches each having a shallow trench isolation (STI) structure are formed. A method of separating the devices by forming the trenches each having the STI structure is briefly described below. A trench is formed by etching a silicon substrate in the field region to a depth of about 3500 Å, and a high-density plasma (HDP) oxide layer is deposited thereon. Next, a chemical mechanical polishing (CMP) process is performed, thereby realizing separation between the devices.

In this case, before the isolation structures are formed, ion implantation for controlling the threshold voltage is performed on the semiconductor substrate using an ion implantation process. A phenomenon in which ions implanted during the ion implantation for controlling the threshold voltage diffuse into the sidewall oxide layer occurs because of the oxidization process. Accordingly, since the ions implanted in order to control the threshold voltage diffuse into the sidewall oxide layer, the active region has an irregular ion concentration distribution. Consequently, the irregular ion concentration distribution generates a hump phenomenon and causes to increase the leakage current leakage.

### BRIEF SUMMARY

An embodiment of the disclosure is directed to a method of manufacturing semiconductor devices, in which side portions of an active region of a semiconductor substrate are exposed by etching predetermined thickness of an isolation structure as much as the junction region depth in a semiconductor device to be formed later during an isolation process, and an STI ion implantation process is performed on the exposed side portions of the active region, so that a cycling characteristic can be improved because an impurity concentration at the edge portion of the active region is maintained and the central and edge portions of a subsequent junction region can be uniformly formed.

An embodiment of this disclosure relates to a method of manufacturing semiconductor devices. According to this embodiment, a tunnel insulating layer, a conductive layer for a floating gate, and a hard mask layer are sequentially formed over a semiconductor substrate. Isolation trenches are formed by etching the hard mask layer, the conductive layer for the floating gate, the tunnel insulating layer, and the semiconductor substrate. Isolation structures are formed by filling the isolation trenches with an insulating layer. Upper sidewalls of the isolation trenches are exposed by etching predetermined thickness of the isolation structures. Ion implantation regions are formed in the exposed upper sidewalls of the isolation trenches by performing an ion implantation process

The exposed top surface of the isolation structure after etching the predetermined thickness of the isolation structure is lower than a depth of a junction region in the semiconductor substrate.

The upper sidewalls of the isolation trenches are exposed by etching about 400 Å to about 500 Å of the isolation structures from a top surface of the semiconductor substrate.

The method preferably further includes, forming a liner insulating layer on the hard mask layer including the isolation trenches after forming the isolation trenches.

The ion implantation process preferably is performed using boron or BF₂. The ion implantation process preferably is performed using an impurity concentration of 0.1 E12 atoms/cm² to 1.0E13 atoms/cm². The ion implantation process preferably is performed at an implantation angle of 1° to 90° with respect to the semiconductor substrate and preferably is performed at a rotation angle of 1° to 45°.

The method preferably further includes, exposing an active region of the semiconductor substrate by etching the hard mask layer, the conductive layer for the floating gate, and the tunnel insulating layer in a direction of a word line after performing the ion implantation process, and performing a source drain ion implantation process.

### BRIEF DESCRIPTION OF THE DRAWINGS

FIGS. 1 to 5 are sectional views showing a method of forming the isolation structures of a semiconductor device according to an embodiment of this disclosure; and

FIG. 6 is a diagram showing the ion implantation directions of an ion implantation process during the ion implantation process of FIG. 5.

### DESCRIPTION OF SPECIFIC EMBODIMENT

Hereinafter, the disclosed embodiment is described in detail in connection with an embodiment with reference to the accompanying drawings. The figures are provided to allow those having ordinary skill in the art to understand the scope of the disclosed embodiment.

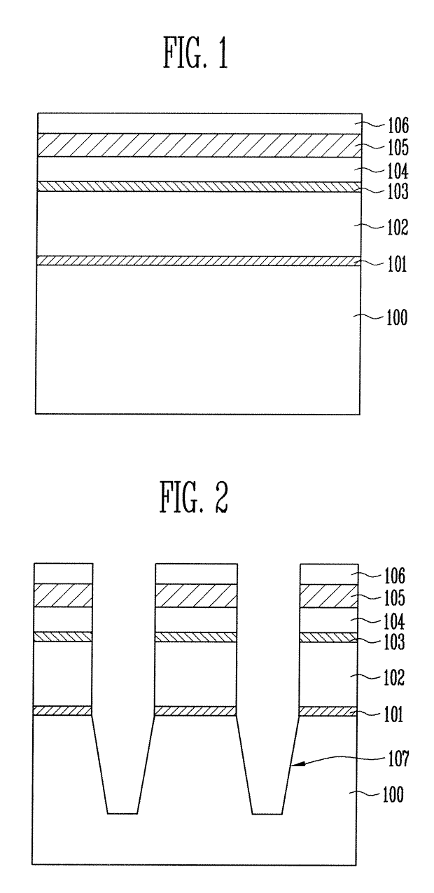

FIGS. 1 to 4 are sectional views showing a method of forming the isolation structures of a semiconductor device according to an embodiment of the disclosure.

Referring to FIG. 1, a tunnel insulating layer 101, a conductive layer for a floating gate 102, a buffer oxide layer 103, a nitride layer for a hard mask 104, an oxide layer for a hard mask 105, and a silicon oxynitride layer for a hard mask 106 are sequentially formed over a semiconductor substrate 100.

Referring to FIG. 2, the silicon oxynitride layer for a hard mask 106, the oxide layer for a hard mask 105, the nitride layer for a hard mask 104, the buffer oxide layer 103, the conductive layer for the floating gate 102, and the gate oxide layer 101 are partially etched using an etch process, thereby exposing specific regions of the semiconductor substrate 100. Isolation trenches 107 are formed by etching the exposed regions of the semiconductor substrate 100.

Referring to FIG. 3, an oxidization process is performed in order to mitigate etch damage occurring during the etch process for forming the isolation trenches 107. A liner insulating layer 108 is formed on the entire surface including the isolation trenches 107. The liner insulating layer 108 preferably is an oxide layer.

Next, an insulating layer 109 for isolating devices is formed on the entire surface including the liner insulating layer 108.

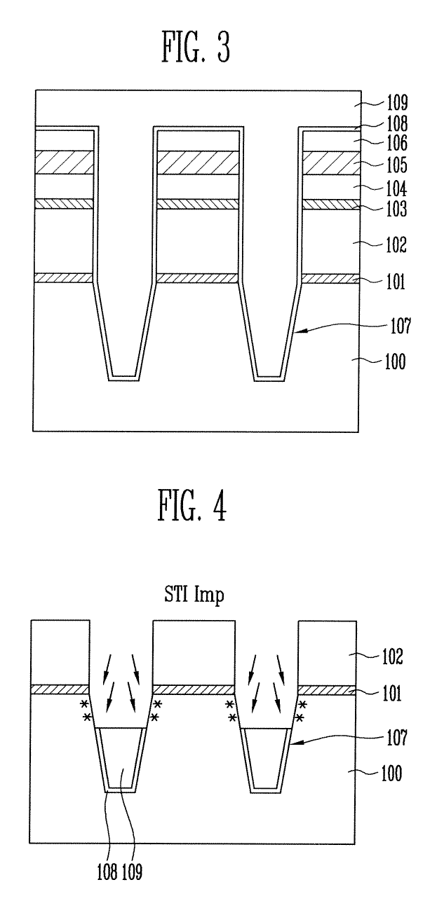

Referring to FIG. 4, isolation structures 108 and 109 are formed by performing a polishing process so that the conductive layer for the floating gate 102 is exposed. The height of the isolation structures 108 and 109 is lowered by performing an additional etch process. In this case, the height of the isolation structures 108 and 109 may be lower than the depth of junction regions (source regions and drain regions) in the semiconductor substrate 100. That is, the exposed top surface of the isolation structures 108 and 109 after etching the predetermined thickness of the isolation structures 108 and 109 is lower tan a depth of the junction regions in the semiconductor. In more detail, the height of the isolation structures 108 and 109 preferably is 400 Å to 500 Å lower than the top surface of active regions of the semiconductor substrate 100. Accordingly, the sidewalls of the isolation trenches are partially exposed. That is, the upper sidewalls of the isolation trenches 107 are exposed by etching about 400 Å to 500 Å of the isolation structures 108 and 109 from the top surface of the semiconductor substrate 100.

Next, ion implantation regions are formed by implanting ions into the surface of the semiconductor substrate 100, exposed through a shallow trench isolation (STI) ion implantation process. The STI ion implantation process preferably is performed using boron or BF₂. The STI ion implantation process preferably is performed at an implantation angle of 1° to 90° with respect to the semiconductor substrate and at a rotation angle of 1° to 45°. The STI ion implantation process preferably is performed using an impurity concentration of 0.1E12 atoms/cm² to 1.0E13 atoms/cm². The STI ion implantation process preferably is performed with energy of 5K to 30K. Accordingly, an STI ion implantation concentration at each of the edge portions of the active region is increased, so Fowler-Nordheim (FN)-tunneling flux occurring at the edge portion of the active region during the program and erase operations of the device can be reduced. Consequently, a cycling characteristic of the device can be improved. Further, the edge and central portions of a junction region to be formed later can be formed uniformly within the active region.

Referring to FIG. 5, the conductive layer for the floating gate 102 and the tunnel insulating layer 101 are etched in the direction of word lines by performing a gate pattern etch process.

Next, an ion implantation process is performed in order to implant junction ions for forming a source and a drain within the semiconductor substrate 100. In a conventional ion implantation process using an incident angle which is vertical to the semiconductor substrate 100, a doping concentration at the junction region and gate edge portions is increased, but a concentration at the edge portion of the active region is lower than that the central portion of the active region.

To prevent this problem, during the ion implantation process, the incident angle is controlled to be 1° to 90° with respect to the semiconductor substrate 100.

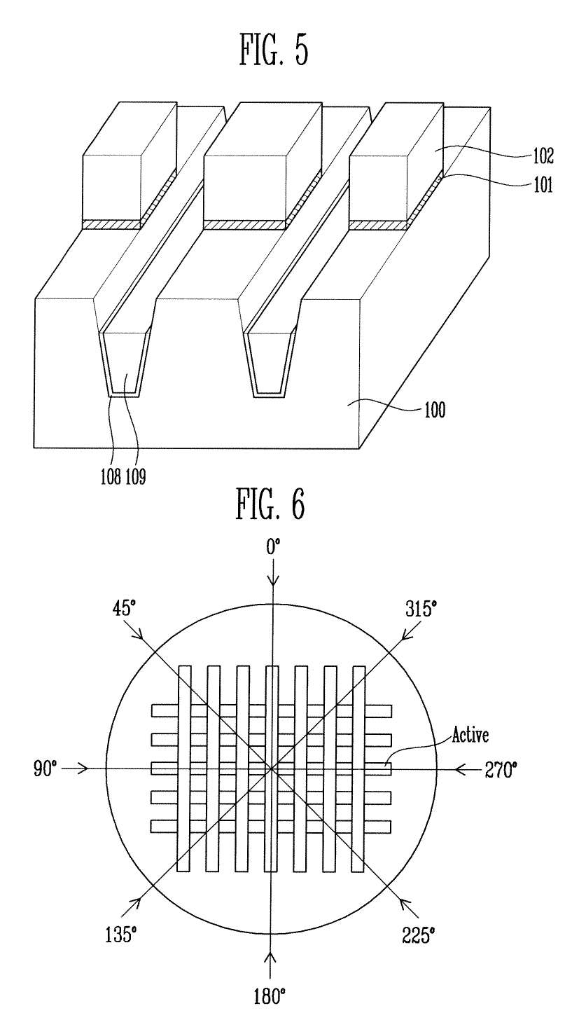

FIG. 6 is a diagram showing the ion implantation directions of an ion implantation process during the ion implantation process of FIG. 5. The ion implantation process may be performed on a wafer in a number of directions (for example, eight directions; 0°, 45°, 90°, 135°, 180°, 225°, 270°, and 315°), not in both directions with respect to a wafer. Alternatively, the ion implantation process may be performed while the wafer is rotated so that the ion implantation process is performed in all directions.

According to an embodiment of the disclosure, the side portions of the active region of the semiconductor substrate are exposed by etching the predetermined thickness of the isolation structure as much as the junction region depth in a semiconductor device to be formed later during an isolation process, and an STI ion implantation process is performed on the exposed side portions of the active region. Accordingly, a cycling characteristic can be improved because an ion impurity concentration at the edge portion of the active region is maintained, and the central and edge portions of a subsequent junction region can be formed uniformly.

What is claimed is:

1. A method of manufacturing semiconductor devices, comprising:
forming a tunnel insulating layer, a conductive layer for a floating gate, and a hard mask layer over a semiconductor substrate;
forming isolation trenches having sidewalls by etching the hard mask layer, the conductive layer for the floating gate, the tunnel insulating layer, and the semiconductor substrate;
forming isolation structures by filling the isolation trenches with an insulating layer;
exposing upper sidewalls of the isolation trenches by etching predetermined thickness of the isolation structures; and
forming ion implantation regions in the exposed upper sidewalls of the isolation trenches by performing an ion implantation process.

2. The method of claim 1, wherein the exposed top surface of the isolation structure after etching the predetermined thickness of the isolation structures is lower than a depth of a junction region in the semiconductor substrate.

3. The method of claim 1, wherein the upper sidewalls of the isolation trenches are exposed by etching about 400 Å to about 500 Å of the isolation structures from a top surface of the semiconductor substrate.

4. The method of claim 1, further comprising,
forming a liner insulating layer on the hard mask layer including the isolation trenches after forming the isolation trenches.

5. The method of claim 1, wherein the ion implantation process is performed using boron or BF₂.

6. The method of claim 1, wherein the ion implantation process is performed using an impurity concentration of 0.1E12 atoms/cm² to 1.0E13 atoms/cm².

7. The method of claim 1, wherein the ion implantation process is performed at an implantation angle of 1° to 90° with respect to the semiconductor substrate and at a rotation angle of 1° to 45°.

8. The method of claim 1, further comprising:
exposing an active region of the semiconductor substrate by etching the hard mask layer, the conductive layer for the floating gate, and the tunnel insulating layer in a direction of a word line after performing the ion implantation process; and
performing a source drain ion implantation process.

9. A method of manufacturing semiconductor devices, comprising:
forming a tunnel insulating layer and a conductive layer for a floating gate over a semiconductor substrate;
forming isolation trenches having sidewalls by etching the conductive layer for the floating gate, the tunnel insulating layer, and the semiconductor substrate;
forming isolation structures by filling the isolation trenches with an insulating layer;
exposing upper sidewalls of the isolation trenches by etching predetermined thickness of the isolation structures;
forming ion implantation regions in the exposed upper sidewalls of the isolation trenches by performing a first ion implantation process;
exposing an active region of the semiconductor substrate by etching the conductive layer for the floating gate and the tunnel insulating layer in a direction of a word line; and
forming a junction region in the exposed active region by performing a second ion implantation process.

10. The method of claim 9, wherein the exposed top surface of the isolation structure after etching the predetermined thickness of the isolation structures is lower than a depth of the junction region in the semiconductor substrate.

11. The method of claim 9, wherein the upper sidewalls of the isolation trenches are exposed by etching about 400 Å to about 500 Å of the isolation structure from a top surface of the semiconductor substrate.

12. The method of claim 9, wherein the first ion implantation process is performed using boron or BF₂.

13. The method of claim 9, wherein the first ion implantation process is performed using an impurity concentration of 0.1E12 atoms/cm² to 1.0E13 atoms/cm².

14. The method of claim 9, wherein the first ion implantation process is performed at an implantation angle of 1° to 90° on the basis of the semiconductor substrate and at a rotation angle of 1° to 45°.

15. The method of claim 9, wherein the second ion implantation process is performed at an implantation angle of 1° to 90° with respect to the semiconductor substrate.

16. The method of claim 9, wherein the second ion implantation process is performed on a wafer at an ion implantation angle with respect to the wafer selected from the group consisting of 0°, 45°, 90°, 135°, 180°, 225°, 270°, and 315°.

17. The method of claim 9, wherein the second ion implantation process is performed on a wafer while rotating the wafer.

18. A method of manufacturing semiconductor devices, comprising:
forming isolation trenches having sidewalls by etching a semiconductor substrate;
forming isolation structures by filling the isolation trenches with an insulating layer;
exposing upper sidewalls of the isolation trenches by etching predetermined thickness of the isolation structures; and
forming ion implantation regions in the exposed upper sidewalls of the isolation trenches by performing an ion implantation process.

19. The method of claim 18, wherein the exposed top surface of the isolation structure after etching the predetermined thickness of the isolation structures is lower than a depth of the junction region in the semiconductor substrate.

20. The method of claim 18, wherein the upper sidewalls of the isolation trenches are exposed by etching about 400 Å to about 500 Å of the isolation structures from a top surface of the semiconductor substrate.

21. The method of claim 18, wherein the ion implantation process is performed using boron or BF₂.

22. The method of claim 18, wherein the ion implantation process is performed using an impurity concentration of 0.1E12 atoms/cm² to 1.0E13 atoms/cm².

23. The method of claim 18, wherein the ion implantation process is performed at an implantation angle of 1° to 90° with respect to the semiconductor substrate and at a rotation angle of 1° to 45°.
